(19) United States
(12) Patent Application Publication
(10) Pub. No.: US 2025/0174584 A1
(43) Pub. Date: May 29, 2025

(54) SEMICONDUCTOR PACKAGE AND METHOD OF MANUFACTURING THE SAME

(71) Applicant: SAMSUNG ELECTRONICS CO., LTD, SUWON-SI (KR)

(72) Inventor: Youngja KIM, Suwon-si (KR)

(21) Appl. No.: 18/825,322

(22) Filed: Sep. 5, 2024

(30) Foreign Application Priority Data
Nov. 28, 2023 (KR) 10-2023-0168408

(51) Int. Cl. H01L 23/00; H01L 21/768; H01L 23/31; H01L 23/498; H01L 25/065; H10B 80/00

(52) U.S. Cl. CPC H01L 24/05; H01L 21/76898; H01L 23/3185; H01L 23/49838; H01L 24/06; H01L 24/32; H01L 25/0657; H01L 2224/05541; H01L 2224/0557; H01L 2224/06131; H01L 2224/32145; H01L 2224/32225; H01L 2924/1431; H10B 80/00

(57) ABSTRACT

A semiconductor package includes semiconductor chips and bonding layers alternately stacked on a package substrate in a vertical direction substantially perpendicular to an upper surface of the package substrate. Each of the semiconductor chips includes a substrate and a conductive pad structure on the substrate. A conductive connection member continuously extends in the vertical direction on the package substrate and directly contacts sidewalls of each of the semiconductor chips, bonding layers and the conductive pad structure. A molding member is disposed on the package substrate, and covers sidewalls of the semiconductor chips and the conductive connection member.

### CROSS-REFERENCE TO RELATED APPLICATION

This application claims priority under 35 U.S.C. § 119 to Korean Patent Application No. 10-2023-0168408, filed on Nov. 28, 2023 in the Korean Intellectual Property Office, the disclosure of which is incorporated by reference in its entirety herein.

### 1. Technical Field

Example embodiments relate to a semiconductor package and a method of manufacturing the semiconductor package. More particularly, example embodiments relate to a multi-chip package including a plurality of stacked chips and a method of manufacturing the multi-chip package.

### 2. Discussion of Related Art

In a semiconductor package that includes a plurality of semiconductor chips stacked in a vertical direction on a package substrate, the semiconductor chips may be electrically connected to the package substrate by various methods, such as a wire bonding method. However, a space must be provided for a bonding wire that directly contacts each of the semiconductor chips so that the semiconductor package may have an increased thickness in the vertical direction. Additionally, conductive pads in the semiconductor chips may have a compact layout so that the bonding wires may not interfere with each other.

### SUMMARY

Example embodiments provide a semiconductor package having increased electrical characteristics.

According to an example embodiment, a semiconductor package includes semiconductor chips and bonding layers alternately stacked on a package substrate in a vertical direction substantially perpendicular to an upper surface of the package substrate. Each of the semiconductor chips includes a substrate and a conductive pad structure on the substrate. A conductive connection member continuously extends in the vertical direction on the package substrate and directly contacts sidewalls of each of the semiconductor chips, bonding layers and the conductive pad structure. A molding member is disposed on the package substrate, and covers sidewalls of the semiconductor chips and the conductive connection member.

According to an example embodiment, a semiconductor package includes semiconductor chips stacked on a package substrate in a vertical direction substantially perpendicular to an upper surface of the package substrate. Each of the semiconductor chips includes a substrate. An insulating interlayer is on the substrate. The insulating interlayer contains a wiring structure therein. A conductive pad structure is on the insulating interlayer.

The conductive pad structure directly contacts the wiring structure. A protective layer is on the insulating interlayer. The protective layer covers at least a sidewall and an upper surface of the conductive pad structure. A bonding layer is between each of the semiconductor chips in the vertical direction. The bonding layer directly contacts an upper surface of the protective layer of a first one of the semiconductor chips and a lower surface of the substrate of a second one of the semiconductor chips. The first one of the semiconductor chips is disposed under the second one of the semiconductor chips. A conductive connection member extends in the vertical direction on the package substrate and directly contacts sidewalls of the substrate and the conductive pad structure in each of the semiconductor chips. A molding member is on the package substrate. The molding member covers sidewalls of the semiconductor chips and the conductive connection member.

According to an example embodiment, a method of manufacturing a semiconductor package includes removing at least a sidewall of each semiconductor chip of a plurality of semiconductor chips to form a first opening. Each of the plurality of semiconductor chips includes a substrate and a conductive pad structure on the substrate. The first opening exposes a sidewall of the conductive pad structure. The plurality of semiconductor chips is stacked in a vertical direction on a package substrate such that the first openings in the plurality of semiconductor chips are aligned with each other in the vertical direction. The aligned first openings form a second opening extending in the vertical direction. A conductive connection member is formed in the second opening by a printing process or a dispensing process. A molding member is formed on the package substrate to cover sidewalls of the plurality of semiconductor chips and the conductive connection member.

In the method of manufacturing the semiconductor package in accordance with example embodiments, the opening may be formed through the semiconductor chip structure including the semiconductor chips stacked in the vertical direction on the package substrate, and the conductive connection member may be formed in the opening by a printing process or a dispensing process so that the conductive connection member may be precisely formed in the opening. Thus, an electrical short between adjacent conductive connection members may be prevented, and the pitch between the adjacent conductive pad structures may be reduced. Additionally, the conductive connection member may fill a space defined by the opening, so as to have a uniform thickness.

### BRIEF DESCRIPTION OF THE DRAWINGS

FIGS. 1 to 3 are a perspective view, a plan view and a cross-sectional view, respectively,

illustrating a semiconductor package in accordance with example embodiments of the present disclosure.

FIGS. 4 to 16 are cross-sectional views, plan views and perspective views illustrating a method of manufacturing a semiconductor package in accordance with example embodiments of the present disclosure.

FIGS. 17 and 18 are plan views illustrating shapes and layouts of the conductive pad structures included in the semiconductor package in accordance with example embodiments of the present disclosure.

FIG. 19 is a cross-sectional view illustrating a semiconductor package in accordance with an example embodiment of the present disclosure.

### DETAILED DESCRIPTION OF EMBODIMENTS

Hereinafter, non-limiting example embodiments will be explained in detail with reference to the accompanying drawings. Hereinafter, two directions substantially orthogonal to each other among horizontal directions that are substantially parallel to an upper surface of a wafer, a substrate or an interposer may be referred to as first and second directions D1 and D2, respectively, and a vertical direction substantially perpendicular to the upper surface of the wafer, the substrate or the interposer may be referred to as a third direction D3. Each of the first to third directions D1, D2 and D3 may include not only a direction shown in the drawings but also a direction that is inverse to the shown direction. Additionally, in some embodiments the first to third directions D1, D2 and D3 may cross each other in various different angles that are not substantially perpendicular to each other.

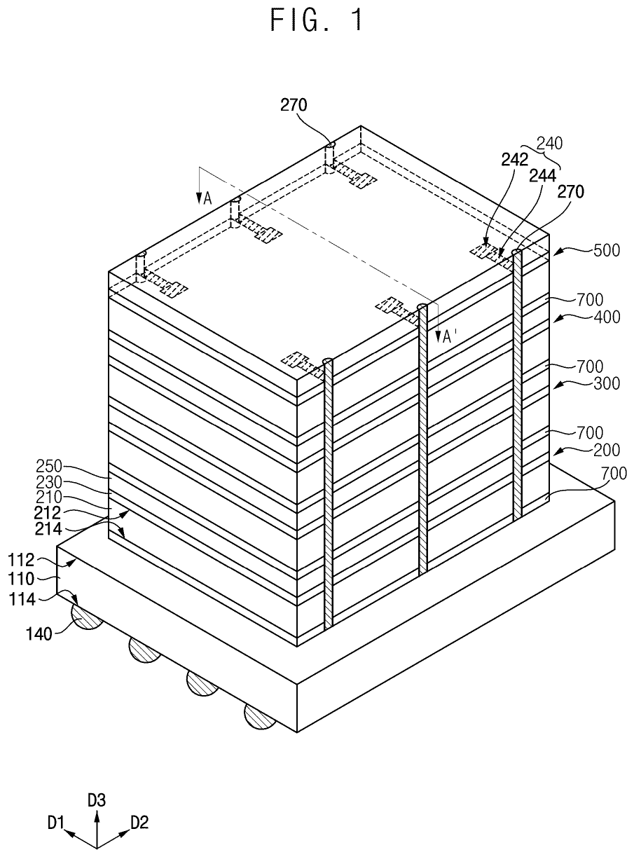

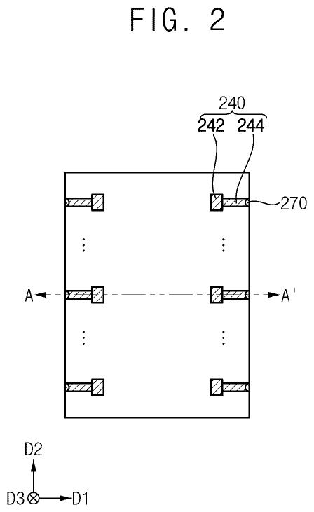

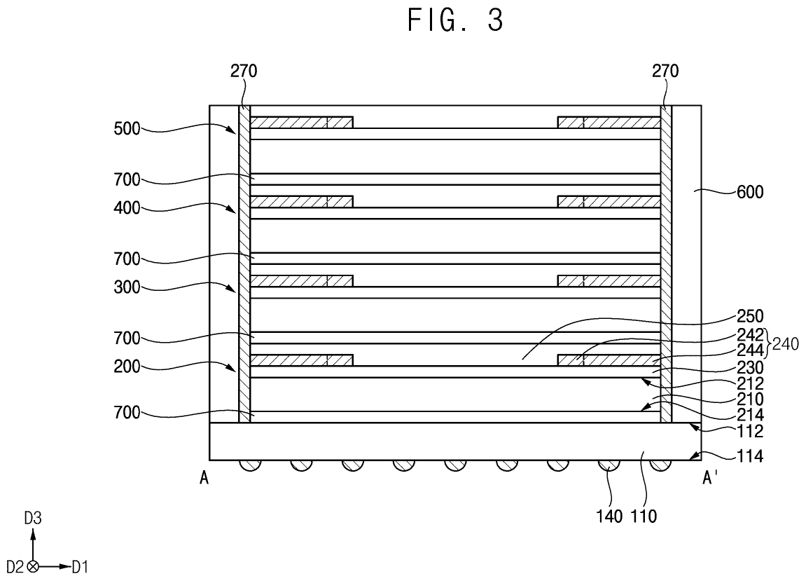

FIGS. 1 to 3 are a perspective view, a plan view and a cross-sectional view, respectively, illustrating a semiconductor package in accordance with example embodiments. Particularly, FIG. 3 is a cross-sectional view taken along line A-A′ of FIGS. 1 and 2.

FIG. 1 does not show a molding member 600, and FIG. 2 does not show the molding member 600 and a protective layer 250, so as to avoid the complexity of the drawings for convenience of explanation.

Referring to FIGS. 1 to 3, in an embodiment the semiconductor package may include a semiconductor chip structure having first, second, third and fourth semiconductor chips 200, 300, 400 and 500 sequentially stacked in the third direction D3 on a first substrate 110 and a bonding layer 700, and a conductive connection member 270 on at least a sidewall of the semiconductor chip structure. For example, the first, second, third and fourth semiconductor chips 200, 300, 400 and 500 and the bonding layers 700 may be alternately stacked in a vertical direction (e.g., the third direction D3). However, embodiments of the present disclosure are not necessarily limited thereto and the number of semiconductor chips stacked on the first substrate 110 of the semiconductor chip structure may vary.

In an embodiment, the semiconductor package may further include a conductive joint member 140 beneath a lower surface of the first substrate 110 and the molding member 600 on an upper surface of the first substrate 110 which covers a sidewall of the semiconductor chip structure.

The first substrate 110 may include first and second surfaces 112 and 114 (e.g., upper and lower surfaces) opposite to each other in the third direction D3. In an example embodiment, the first substrate 110 may be a package substrate, such as a printed circuit board (PCB), which may be a multi-layer circuit board having various circuits therein. Alternatively, in an example embodiment the first substrate 110 may be an interposer substrate that may include a redistribution layer (RDL) containing wirings, vias, contact plugs, conductive pads, etc.

In example embodiments, a plurality of conductive joint members 140 may be spaced apart from each other in the horizontal direction (e.g., the first and/or second directions D1, D2). In an embodiment, each of the conductive joint member 140 may include, a conductive bump, which may include a metal, such as copper, aluminum, nickel, etc., or solder that is an alloy including tin, silver, copper, lead, etc. However, embodiments of the present disclosure are not necessarily limited thereto.

In example embodiments, the first semiconductor chip 200 may include a second substrate 210 having first and second surfaces 212 and 214 (e.g., upper and lower surfaces) opposite to each other in the third direction D3, and a first insulating interlayer and a second insulating interlayer 230 may be sequentially stacked on the first surface 212 of the second substrate 210 in the third direction D3.

In an embodiment, the second substrate 210 may include a semiconductor material, such as silicon, germanium, silicon-germanium, etc., or a III-V group compound semiconductor, such as GaP, GaAs, GaSb, etc. In example embodiments, the second substrate 210 may be a silicon-on-insulator (SOI) substrate or a germanium-on-insulator (GOI) substrate.

In an embodiment, a circuit device, such as a logic device or a memory device may be formed on the first surface 212 of the second substrate 210. In an embodiment, the memory device may include a volatile memory device such as a DRAM device, an SRAM device, etc., or a non-volatile memory device such as a flash memory device, an EEPROM device, etc. The circuit device may include circuit patterns, which may be covered by the first insulating interlayer.

In an embodiment, the second insulating interlayer 230 may contain a wiring structure therein. For example, the wiring structure may include wirings, vias, contact plugs, etc.

In an embodiment, the first insulating interlayer and the second insulating interlayer 230 may include an oxide, such as silicon oxide, an insulating nitride, such as silicon nitride, or a low-k dielectric material. In an embodiment, the wirings, the vias and the contact plugs may include a metal, a metal nitride, a metal silicide, etc.

In an embodiment, a conductive pad structure including a conductive pad 242 and a sub-conductive pad 244 may be formed on the second insulating interlayer 230. The conductive pad structure may be electrically connected to the wiring structure contained in the second insulating interlayer 230, and may be covered by the protective layer 250 on the second insulating interlayer 230.

In example embodiments, a plurality of conductive pad structures 240 may be spaced apart from each other in the horizontal direction (e.g., the first and/or second directions D1, D2).

In an example embodiment, the conductive pad structure 240 may be disposed on each of opposite edge portions in the first direction DI of the first semiconductor chip 200, and a plurality of conductive pad structures 240 may be spaced apart from each other in the second direction D2. However, embodiments of the present disclosure are not necessarily limited thereto. In an embodiment, each of the sub-conductive pads 244 may extend longitudinally in the first direction DI from each of opposite sidewalls in the first direction D1 of the first semiconductor chip 200 towards a central portion of the first semiconductor chip 200, and the conductive pad 242 may directly contact an end portion in the first direction D1 of the sub-conductive pad 244. For example, the conductive pad 242 may directly contact the end portion of the sub-conductive pad 244 that is farthest from the sidewall (e.g., in the first direction D1) of the first semiconductor chip 200 and closest to the central portion of the first semiconductor chip 200.

However, the shape and layout of the conductive pad structure 240 is not necessarily limited to those of the conductive pad structure 240 shown in FIGS. 1 to 3.

For example, in some embodiments the sub-conductive pad 244 may extend longitudinally in the second direction D2, and the conductive pad 242 may directly contact an end portion in the second direction D2 of the sub-conductive pad 244. Alternatively, in an embodiment the sub-conductive pad 244 may include a first extension portion extending longitudinally in the first direction D1, and a second extension portion extending longitudinally in the second direction D2 and being connected to the first extension portion.

Additionally, in an embodiment the conductive pad structure 240 may be disposed on a central portion of the first semiconductor chip 200 instead of on each of opposite edge portions in the first direction D1 of the first semiconductor chip 200.

In an example embodiment, a width in the second direction D2 of the conductive pad 242 may be greater than a width in the second direction D2 of the sub-conductive pad 244, and a thickness in the third direction D3 of the conductive pad 242 may be substantially equal to a thickness in the third direction D3 of the sub-conductive pad 244.

However, embodiments of the present disclosure are not necessarily limited thereto. For example, in an embodiment the width in the second direction D2 of the conductive pad 242 may also be less than or substantially equal to that of the sub-conductive pad 244, and the thickness in the third direction D3 of the conductive pad 242 may also be greater than or less than that of the sub-conductive pad 244.

In an embodiment, the conductive pad 242 and the sub-conductive pad 244 may include, for example, aluminum, copper, tin, nickel, gold, platinum, or an alloy thereof.

In example embodiments, the protective layer 250 may cover an upper surface and a sidewall of the conductive pad structure 240. In an embodiment, the protective layer 250 may include an oxide, such as silicon oxide or an insulating nitride, such as silicon nitride. However, embodiments of the present disclosure are not necessarily limited thereto.

The first semiconductor chip 200 may be bonded with the upper surface of the first substrate 110 through the bonding layer 700 beneath a lower surface of the first semiconductor chip 200. In an embodiment, the bonding layer 700 may include, for example, a die attach film (DAF). However, embodiments of the present disclosure are not necessarily limited thereto.

In an embodiment, each of the second to fourth semiconductor chips 300, 400 and 500 may have a structure substantially the same as that of the first semiconductor chip 200, and may be bonded with the first to third semiconductor chips 200, 300 and 400, respectively, through the bonding layer 700 therebeneath.

In example embodiments, the conductive connection member 270 may extend in the third direction D3 on each of opposite sidewalls in the first direction D1 of the semiconductor chip structure, and may directly contact sidewalls of the sub-conductive pad 244 included in each of the first to fourth semiconductor chips 200, 300, 400 and 500 to be electrically connected thereto. For example, the conductive connection member 270 may directly contact at least one sidewall of each of the first to fourth semiconductor chips 200, 300, 400 and 500, the bonding layers 700 disposed therebetween and the sub-conductive pad 244 included in each of the first to fourth semiconductor chips 200, 300, 400 and 500. Additionally, the conductive connection member 270 may directly contact the upper surface of the first substrate 110 to be electrically connected to the circuit patterns in the first substrate 110.

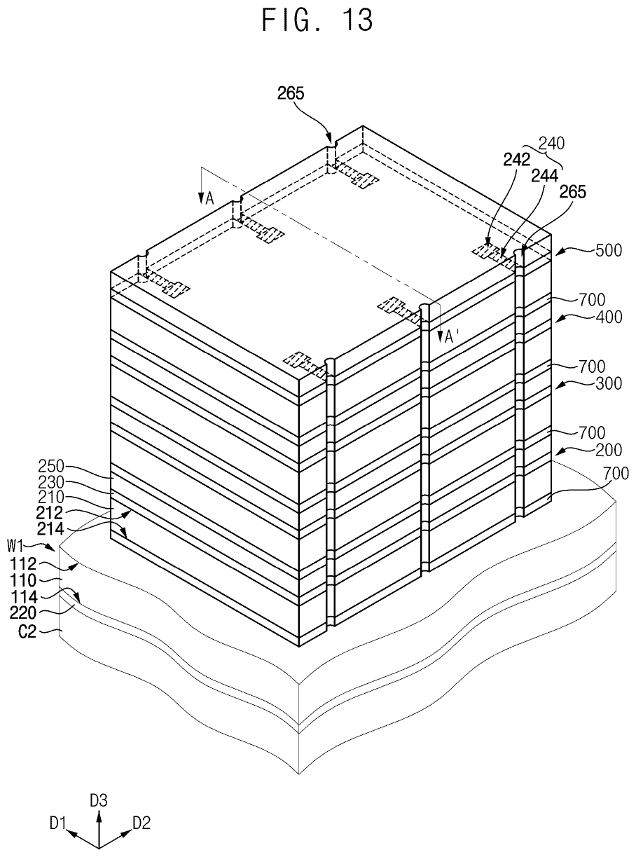

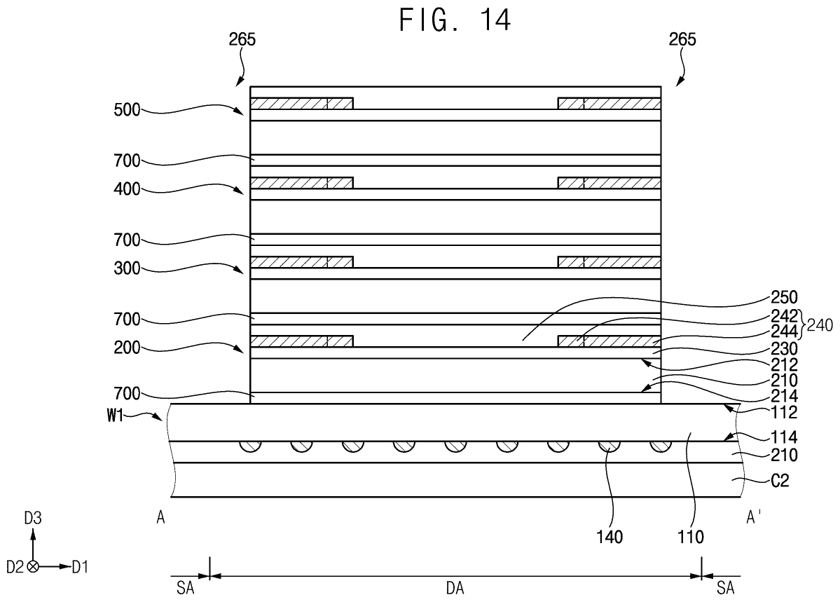

In example embodiments, the conductive connection member 270 may be formed in a second opening 265 (refer to FIGS. 13 and 14) extending through each of opposite edge portions in the first direction D1 of the semiconductor chip structure. In example embodiments, a plurality of second openings 265 may be spaced apart from each other in the second direction D2. A plurality of conductive connection members 270 disposed in the plurality of second openings 265, respectively, may be spaced apart from each other in the second direction D2.

In example embodiments, the conductive connection member 270 may have a shape of, for example, a semi-circle, a semi-ellipse, a polygon or a polygon with rounded corners in a plan view (e.g., in a plane defined in the first and second directions D1, D2), and may include, for example, gold. However, embodiments of the present disclosure are not necessarily limited thereto.

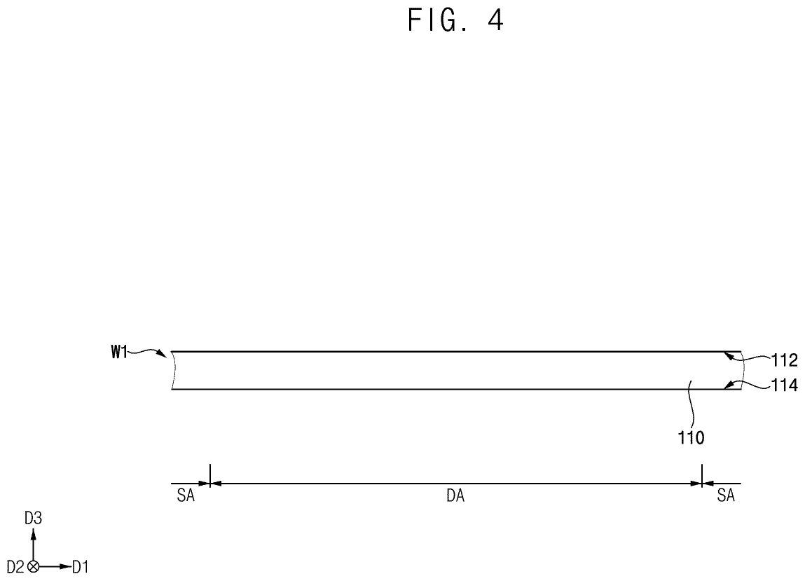

As illustrated below with reference to FIGS. 4 to 16, in an embodiment the conductive connection members 270 may be formed only in the second openings 265, respectively, and thus an electrical short may be prevented from occurring between adjacent ones of the conductive connection members 270. Additionally, in an embodiment the conductive connection members 270 may be disposed to be spaced apart from each other by a relatively small distance due to the low possibility of an occurrence of an electrical short. Accordingly, a pitch between the conductive pad structures 240 connected to the conductive connection members 270, respectively, that are disposed in the second direction D2, such as a pitch between the sub-conductive pads 244 disposed in the second direction D2 may be reduced.

Further, in an embodiment, each of the conductive connection members 270 may have a uniform thickness, and thus may have a uniform quality.

In an embodiment in which the first to fourth semiconductor chips 200, 300, 400 and 500 are electrically connected to the circuit patterns of the first substrate 110 by a wire bonding method, a space should be provided sufficient for a bonding wire directly contacting an upper surface of each of the first to fourth semiconductor chips 200, 300, 400 and 500 so that the semiconductor chip structure may have an increased thickness in the third direction D3. Additionally, a portion of the protective layer 250 covering the conductive pad 242 should be removed to at least partially expose an upper surface of the conductive pad 242 so that the bonding wire may directly contact the conductive pad 242.

Furthermore, the first to fourth semiconductor chips 200, 300, 400 and 500 cannot be aligned in the third direction D3, but should be offset with each other so that at least a portion of the upper surface of each of the first to fourth semiconductor chips 200, 300, 400 and 500 may be exposed.

However, in example embodiments, each of the first to fourth semiconductor chips 200, 300, 400 and 500 may be electrically connected to the circuit patterns in the first substrate 110 through the conductive connection member 270 directly contacting a sidewall of the sub-conductive pad 244 included in the conductive pad structure 240, and thus the thickness in the third direction D3 of the semiconductor chip structure may be reduced. Additionally, the protective layer 250 may not partially expose the upper surface of the conductive pad structure 240, and may entirely cover the upper surface of the conductive pad structure 240. Thus, the conductive pad structure 240 may have increased protection by the protective layer 250.

Furthermore, the bonding wire may not directly contact the upper surface of each of the second to fourth semiconductor chips 300, 400 and 500. Therefore, the sidewalls of the second to fourth semiconductor chips 300, 400 and 500 may be aligned with each other in the third direction D3. For example, the second to fourth semiconductor chips 300, 400 and 500 may be disposed in the same area in a plan view (e.g., in a plane defined in the first and second directions D1, D2), and may be overlapped with each other in the third direction D3. Accordingly, a planar area of the semiconductor chip structure may be reduced so that the semiconductor package including the semiconductor chip structure may have a reduced size.

In an embodiment, the molding member 600 may include a polymer, such as epoxy molding compound (EMC). However, embodiments of the present disclosure are not necessarily limited thereto.

FIGS. 4 to 16 are cross-sectional views, plan views and perspective views illustrating a method of manufacturing a semiconductor package in accordance with example embodiments.

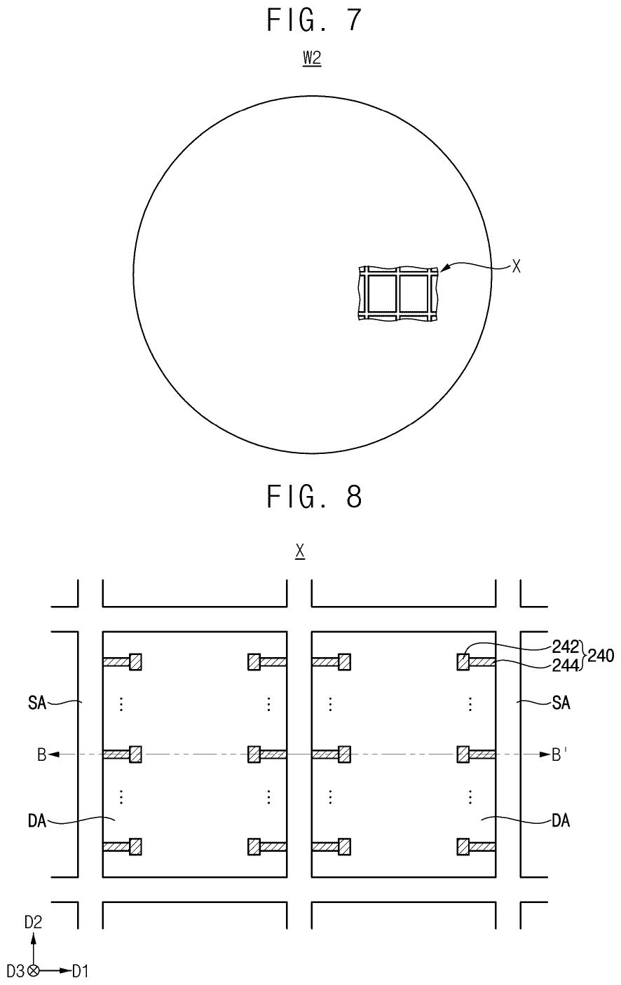

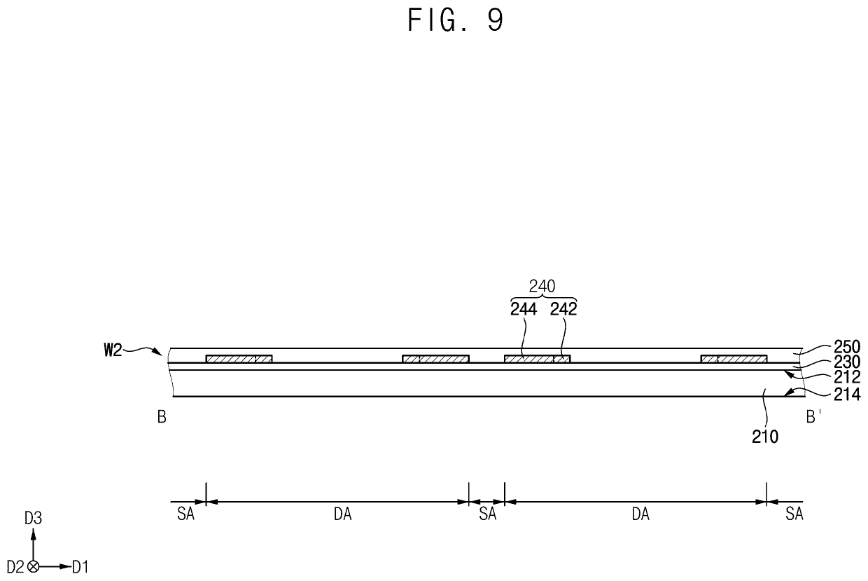

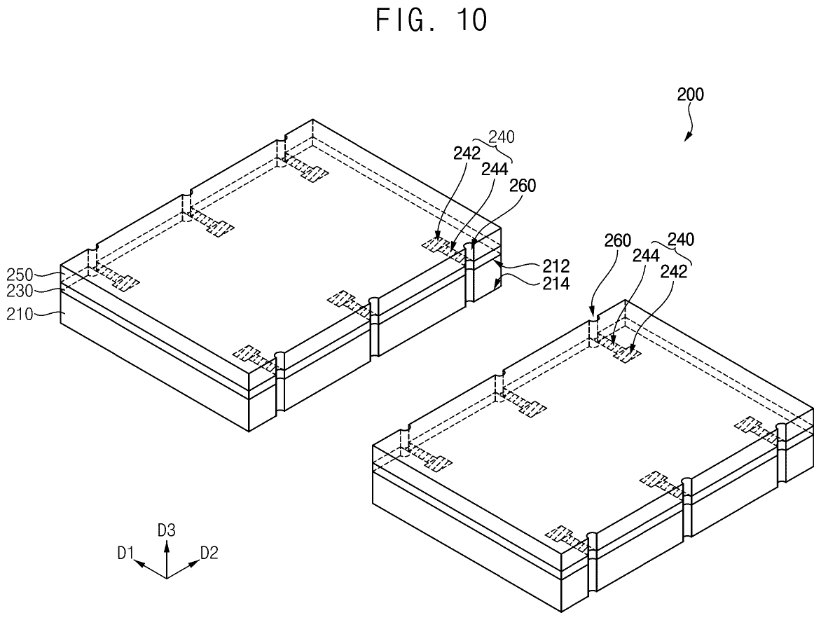

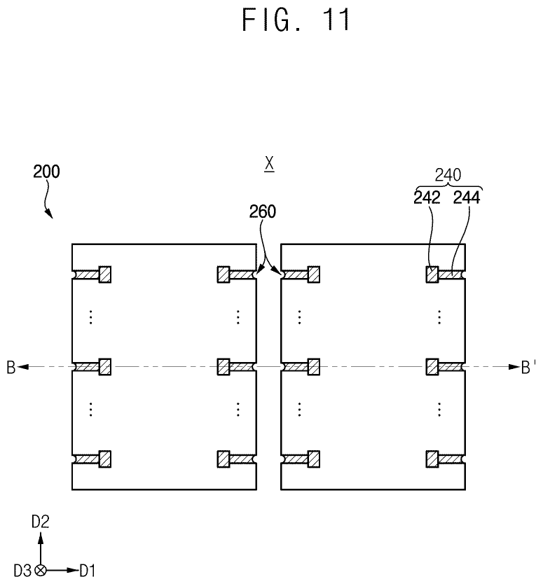

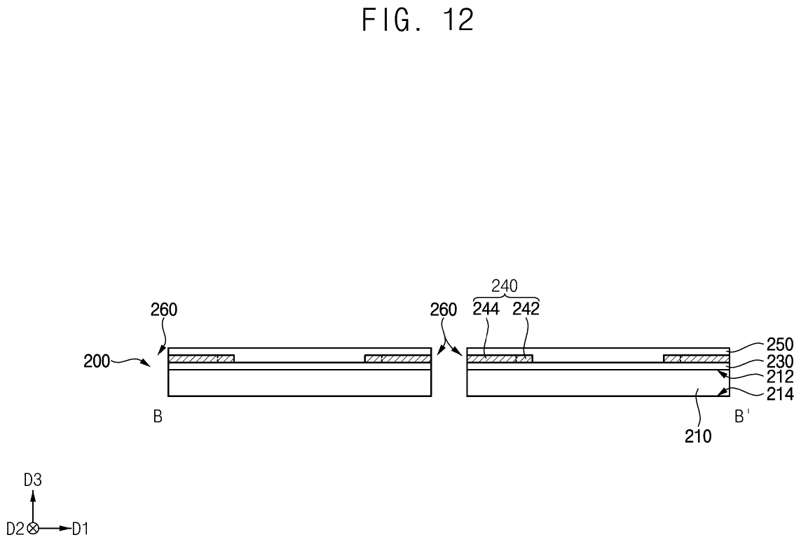

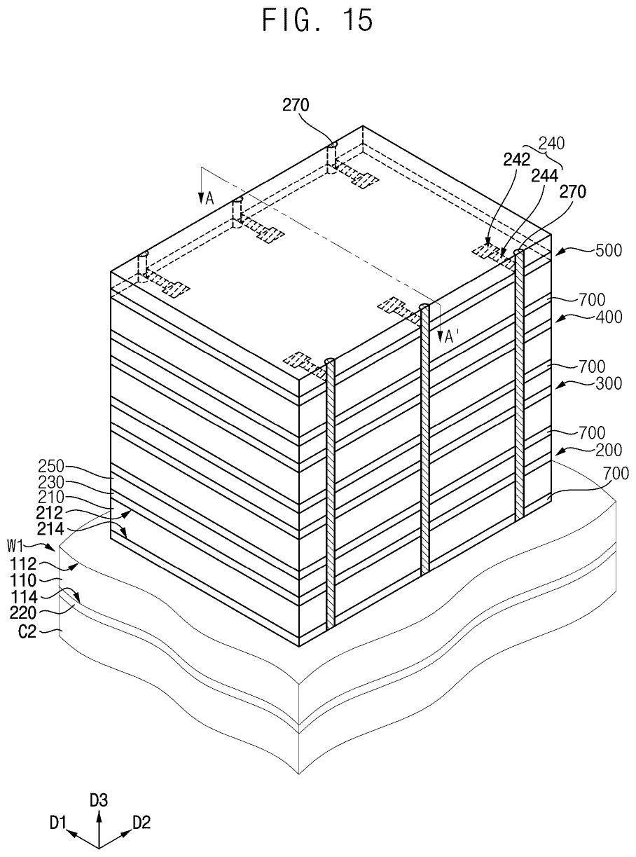

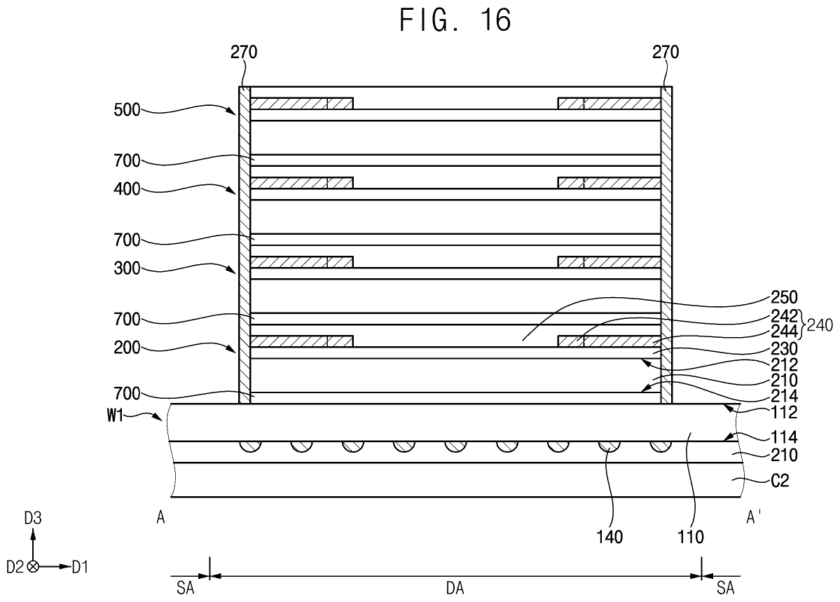

Particularly, FIGS. 4-6, 9, 12, 14 and 16 are the cross-sectional views, FIGS. 7, 8 and 11 are the plan views, and FIGS. 10, 13 and 15 are the perspective views. FIGS. 8 and 11 are plan views of region X in FIG. 7, FIGS. 9 and 12 are cross-sectional views taken along lines B-B′ of FIGS. 8 and 11, respectively, and FIGS. 14 and 16 are cross-sectional views taken along lines A-A′ of FIGS. 13 and 15, respectively.

FIGS. 8 and 11 do not show a protective layer 250 to avoid the complexity of the drawings for convenience of explanation.

Referring to FIG. 4, a first wafer W1 including a plurality of first substrates 110 may be provided.

In example embodiments, the first wafer W1 may include the first substrate 110 having first and second surfaces 112 and 114 (e.g., upper and lower surfaces) opposite to each other in the third direction D3. Additionally, in an embodiment the first wafer W1 may include a plurality of die regions DA and a scribe lane region SA surrounding each of the die regions DA (e.g., in the first and/or second directions D1, D2). The first wafer W1 may be cut along the scribe lane region SA by a sawing process to be singulated into the first substrates 110.

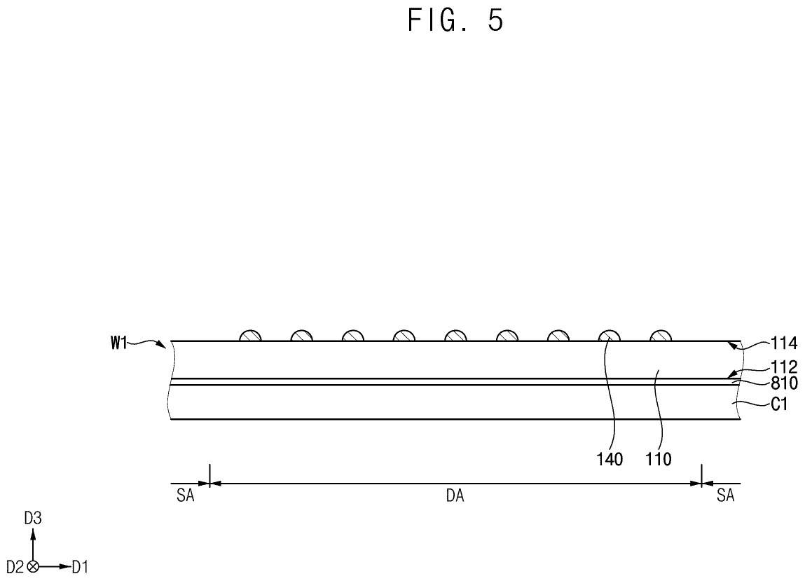

Referring to FIG. 5, a first temporary bonding layer 810 may be attached to (e.g., disposed directly thereon) a first carrier substrate C1. In an embodiment, the first carrier substrate C1 may be bonded to the first wafer W1 such that the first temporary bonding layer 810 may directly contact the first surface 112 of the first substrate 110, and a structure including the first wafer W1 and the first carrier substrate C1 may be overturned.

In an embodiment, the first carrier substrate C1 may include, for example, a non-metal plate, a metal plate, a silicon substrate, a glass substrate, etc. However, embodiments of the present disclosure are not necessarily limited thereto. The first temporary bonding layer 810 may include a material that may lose adhesion by an irradiation of light or heating. In an example embodiment, the first temporary bonding layer 810 may include a release tape. However, embodiments of the present disclosure are not necessarily limited thereto.

In an embodiment, a conductive joint member 140 may be formed on (e.g., disposed directly thereon) the second surface 114 of the first wafer W1. In example embodiments, a plurality of conductive joint members 140 may be spaced apart from each other in the horizontal direction (e.g., the first and/or second directions D1, D2). The conductive joint member 140 may include, for example, a conductive bump. However, embodiments of the present disclosure are not necessarily limited thereto.

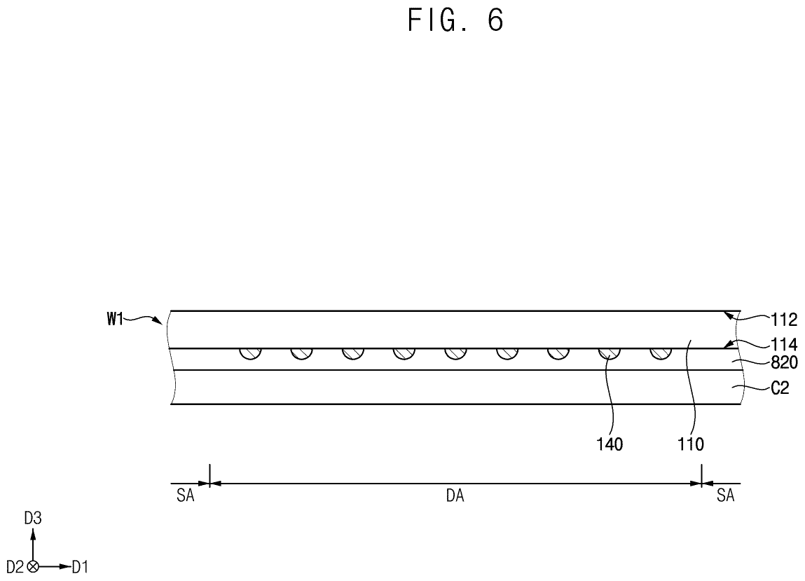

Referring to FIG. 6, a second temporary bonding layer 820 may be attached to (e.g., disposed directly thereon) a second carrier substrate C2. In an embodiment, the second carrier substrate C2 may be bonded to the first wafer W1 such that the second temporary bonding layer 820 may directly contact the second surface 114 of the first substrate 110, and a structure including the first wafer W1 and the first and second carrier substrates C1 and C2 may be overturned.

In an embodiment, the second carrier substrate C2 may include, for example, a non-metal plate, a metal plate, a silicon substrate, a glass substrate, etc. However, embodiments of the present disclosure are not necessarily limited thereto. In an embodiment, the second temporary bonding layer 820 may include a material that may lose adhesion by an irradiation of light or heating. For example, in an embodiment, the second temporary bonding layer 820 may include glue.

The first temporary bonding layer 810 attached to the first wafer W1 may be separated from the first substrate 110, so that the first carrier substrate C1 may be separated from the first wafer W1 and that the first surface 112 of the first substrate 110 may be exposed.

Referring to FIGS. 7 to 9, a second wafer W2 including a plurality of second substrates 210 may be provided.

In example embodiments, the second wafer W2 may include the second substrate 210 having first and second surfaces 212 and 214 (e.g., upper and lower surfaces) opposite to each other in the third direction D3, and a first insulating interlayer and a second insulating interlayer 230 may be sequentially stacked on the second surface 212 of the second substrate 210.

Additionally, in an embodiment the second wafer W2 may include a plurality of die regions DA and a scribe lane region SA surrounding each of the die regions DA (e.g., in the first and/or second directions D1, D2). In an embodiment, the second wafer W1 may be cut along the scribe lane region SA by a sawing process to be singulated into first semiconductor chips.

In an embodiment, a circuit device, such as a logic device or a memory device may be formed on the first surface 212 of the second substrate 210. In an embodiment, the circuit device may include circuit patterns, which may be covered by the first insulating interlayer. The second insulating interlayer 230 may contain a wiring structure disposed therein.

In an embodiment, a conductive pad structure 240 including a conductive pad 242 and a sub-conductive pad 244 may be formed on (e.g., disposed directly thereon) the second insulating interlayer 230, and may be electrically connected to the wiring structure in the second insulating interlayer 230. The conductive pad structure 240 may be covered by the protective layer 250.

In example embodiments, a plurality of conductive pad structures 240 may be spaced apart from each other in the horizontal direction (e.g., in the first and/or second directions D1, D2).

For example, in an embodiment, the conductive pad structure 240 may be disposed on each of opposite edge portions in the first direction DI of each of the die regions DA, and a plurality of conductive pad structures 240 may be spaced apart from each other in the second direction D2. In an embodiment, each of the sub-conductive pads 244 may extend longitudinally in the first direction D1 from the scribe lane region SA into the die region DA, and the conductive pad 242 may directly contact an end portion in the first direction D1 of the sub-conductive pad 244.

In an example embodiment, a width in the second direction D2 of the conductive pad 242 may be greater than a width in the second direction D2 of the sub-conductive pad 244, and a thickness in the third direction D3 of the conductive pad 242 may be substantially equal to a thickness in the third direction D3 of the conductive pad 244. However, embodiments of the present disclosure are not necessarily limited thereto.

Referring to FIGS. 10 to 12, in an embodiment the second wafer W2 may be cut along the scribe lane region SA by, for example, a sawing process to be singulated into a plurality of first semiconductor chips 200, and a first opening 260 may be formed through the second substrate 210, the first insulating interlayer, the second insulating interlayer 230 and the protective layer 250 in each of the first semiconductor chips 200 to expose a sidewall of an end portion in the first direction D1 of the sub-conductive pad 244. In an embodiment, the first opening 260 may also extend through the end portion in the first direction D1 of the sub-conductive pad 244.

In an example embodiment, the first opening 260 may be formed by a mechanical method, such as by using a blade or a drill. Alternatively, the first opening 260 may be formed by a sawing process, such as by using plasma or laser. Alternatively, the first opening 260 may be formed by a dry etching process using an etching gas. However, embodiments of the present disclosure are not necessarily limited thereto.

In an embodiment, the first opening 260 may have a shape in a plan view (e.g., in a plane defined in the first and/or second directions D1, D2) of, for example, a semi-circle, a semi-ellipse, a polygon or a polygon with rounded corners. In example embodiments, a plurality of first openings 260 may be spaced apart from each other in the horizontal direction (e.g., the second direction D2) according to the layout of the conductive pad structure 240. Thus, as shown in FIG. 10, a plurality of first openings 260 may be spaced apart from each other in the second direction D2 at each of opposite edge portions in the first direction DI of each of the first semiconductor chips 200.

Referring to FIGS. 13 and 14, a bonding layer 700, such as a die attach film (DAF) may be attached to (e.g., disposed directly on) a lower surface of the first semiconductor chip 200, and the bonding layer 700 may also be bonded with an upper surface of the first wafer W1.

Additionally, a plurality of semiconductor chips to each of which the bonding layer 700 is attached, such as a second, third and fourth semiconductor chips 300, 400 and 500, may be sequentially stacked in the third direction D3 on the first semiconductor chip 200. However, embodiments of the present disclosure are not necessarily limited thereto and the number of semiconductor chips in the plurality of semiconductor chips may vary.

The first to fourth semiconductor chips 200, 300, 400 and 500 sequentially stacked on the first wafer W1 and the bonding layers 700 therebetween (e.g., in the third direction D3) may collectively form a semiconductor chip structure.

In example embodiments, the first to fourth semiconductor chips 200, 300, 400 and 500 may be stacked such that the first openings 260 in the first to fourth semiconductor chips 200, 300, 400 and 500 may be aligned with each other in the third direction D3, and hereinafter, the first openings 260 aligned with each other in the third direction D3 may be collectively referred to as a second opening 265. In an embodiment, the second opening 265 may expose the upper surface of the first wafer W1, and a plurality of second openings 265 may be spaced apart from each other in the second direction D2 at each of opposite edge portions in the first direction D1 of the semiconductor chip structure.

Referring to FIGS. 15 and 16, a conductive connection member 270 may be formed in the second opening 265.

In an example embodiment, the conductive connection member 270 may be formed by, for example, a printing process or a dispensing process. In an embodiment, the conductive connection member 270 may include, or be formed of, paste including a metal, such as gold. However, embodiments of the present disclosure are not necessarily limited thereto.

In example embodiments, during the printing process or the dispensing process, the second opening 265 may serve as a guide for defining a space in which the conductive connection member 270 is formed. Therefore, the conductive connection member 270 may be formed only in the second opening 265.

In a comparative embodiment in which the printing process or a dispensing process is performed to form the conductive connection member 270 without forming the second opening 265, due to characteristics of a metal paste, an area for forming the conductive connection member 270 may not be precisely controlled, and thus some of the conductive connection members 270 adjacent to each other in the second direction D2 may directly contact each other to generate electrical short. Additionally, the conductive connection member 270 may not have a uniform thickness, so that the characteristics of the conductive connection member 270 may not be controlled.

However, in example embodiments, before forming the conductive connection member 270, the second opening 265 may be formed to limit the area for forming the conductive connection member 270. Therefore, the conductive connection member 270 that may be formed by the printing process or the dispensing process may be precisely formed in the second opening 265, and an electrical short between adjacent ones of the conductive connection members 270 may be prevented. Additionally, the conductive connection member 270 may be formed to fill the space that may be defined by the second opening 265, so as to have a uniform thickness.

Alternatively, in an embodiment, the conductive connection member 270 may be formed in the second opening 265 by an electroplating process or an electroless plating process. In an embodiment, the conductive connection member 270 may include a metal, such as copper, aluminum, etc. In an embodiment, the conductive connection member 270 may be directly formed in the second opening 265, or after forming the conductive connection member 270 on another substrate, the conductive connection member 270 may be moved onto the first wafer W1 to be inserted into the second opening 265.

In an embodiment, the conductive connection member 270 in the second opening 265 may directly contact a sidewall of the sub-conductive pad 244 exposed by the second opening 265, and thus the sub-conductive pads 244 included in the first to fourth semiconductor chips 200, 300, 400 and 500, respectively, may be electrically connected to each other by the conductive connection member 270.

Referring to FIGS. 1 to 3 again, a molding member 600 may be formed on the first wafer W1 to cover the semiconductor chip structure. In some embodiments, an upper portion of the molding member 600 may be removed, such as by a grinding process, to expose an upper surface of the semiconductor chip structure. However, embodiments of the present disclosure are not necessarily limited thereto and the molding member 600 may cover the upper surface of the semiconductor chip structure in some embodiments.

The first wafer W1 may be cut along the scribe lane region SA, such as by a sawing process to be singulated into a plurality of individual first substrates 110.

During the sawing process, the molding member 600 on the first wafer W1 may also be cut to cover a sidewall of the semiconductor chip structure on the singulated first substrate 110.

In an embodiment, the second temporary bonding layer 820 attached to the first substrate 100 may be separated from the first substrate 110, so that the second carrier substrate C2 may be separated from the first substrate 110. Thus, the manufacturing of the semiconductor package may be completed.

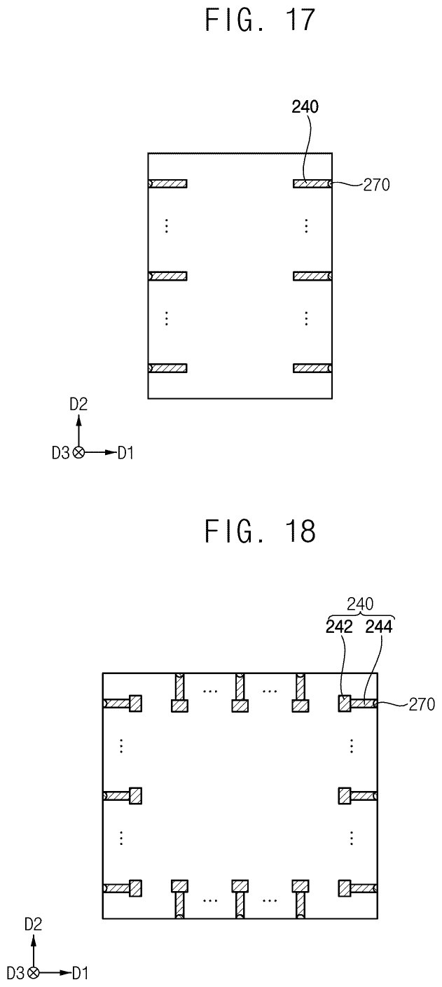

FIGS. 17 and 18 are plan views illustrating shapes and layouts of the conductive pad structures included in the semiconductor package in accordance with example embodiments, which may correspond to FIG. 2. This semiconductor package may be substantially the same as or similar to that of FIGS. 1 to 3, and thus repeated explanations of similar or identical elements may be omitted herein for economy of explanation.

Referring to FIG. 17, in an embodiment the conductive pad structure 240 may include a single structure instead of the conductive pad 242 and the sub-conductive pad 244.

In example embodiments, each of the first to fourth semiconductor chips 200, 300, 400 and 500 may be electrically connected to the first substrate 110 through the conductive connection member 270 extending through the semiconductor chip structure, instead of a wire bonding method, and thus a conductive pad for directly contacting the bonding wire is not needed.

As a result, in an embodiment each of the first to fourth semiconductor chips 200, 300, 400 and 500 may not include the conductive pad 242, but may include only the sub-conductive pad 244 directly contacting the conductive connection member 270. Thus, each of the first to fourth semiconductor chips 200, 300, 400 and 500 may include the conductive pad structure 240 having a single structure.

Referring to FIG. 18, in an embodiment the conductive pad structure 240 may be formed not only at each of opposite edge portions in the first direction DI of each of the first to fourth semiconductor chips 200, 300, 400 and 500 but also at each of opposite edge portions in the second direction D2 thereof, and the conductive connection member 270 may also be formed on each of opposite sidewalls in the second direction D2 of each of the first to fourth semiconductor chips 200, 300, 400 and 500 as well as on each of opposite sidewalls in the first direction D1 thereof.

As illustrated above, each of the first to fourth semiconductor chips 200, 300, 400 and 500 may be electrically connected to the first substrate 110 by the conductive connection member 270 extending through the semiconductor chip structure, instead of a wire bonding method, and thus the layout of the conductive pad structure 240 may not necessarily be limited by the bonding wire. For example, in an embodiment, the conductive pad structure 240 may only include the sub-conductive pad 244 and may not include the conductive pad 242 in some embodiments.

Accordingly, the conductive pad structures 240 may be disposed by various layouts in each of the first to fourth semiconductor chips 200, 300, 400 and 500 in addition to the layout of the conductive pad structure 240 shown in FIGS. 1 to 3 or FIG. 18, and the conductive connection member 270 may also be disposed on at least one of the four sidewalls of the semiconductor chip structure.

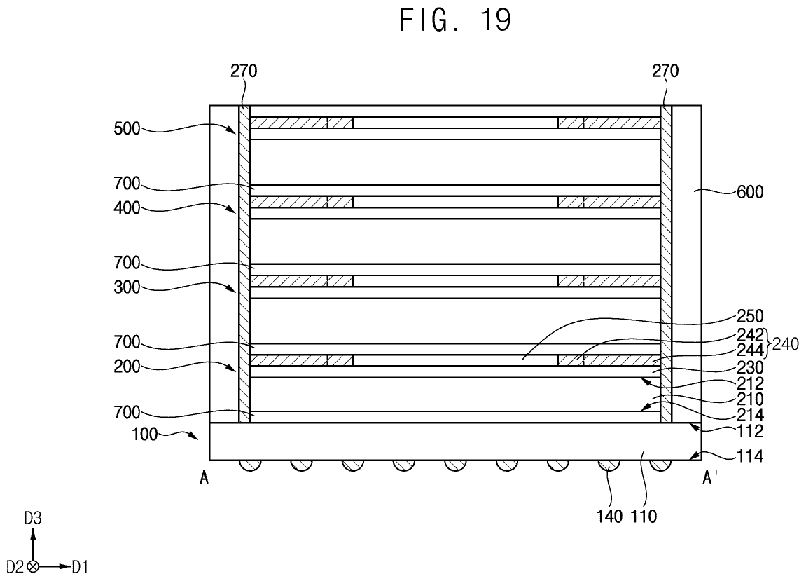

FIG. 19 is a cross-sectional view illustrating a semiconductor package in accordance with example embodiments, which may correspond to FIG. 3. This semiconductor package may be substantially the same as or similar to that of FIGS. 1 to 3, except for the protective layer, and thus repeated explanations of identical or similar elements may be omitted herein for convenience of explanation.

Referring to FIG. 19, the protective layer 250 in each of the first to fourth semiconductor chips 200, 300, 400 and 500 may not cover an upper surface of the conductive pad structure 240, but may cover only a sidewall of the conductive pad structure 240. For example, in an embodiment an upper surface of the protective layer 250 may be co-planar with an upper surface of the conductive pad structure 240 (e.g., in the third direction D3). The protective layer 250 may expose an upper surface of the conductive pad structure 240.

Thus, each of the first to fourth semiconductor chips 200, 300, 400 and 500 in an embodiment shown in FIG. 19 may have a thickness in the third direction D3 that is less than a thickness in the third direction D3 of a semiconductor chip in an embodiment shown in FIG. 3 that includes a protective layer 250 covering the upper surface of the conductive pad structure 240.

In example embodiments, the semiconductor chip structure including the first to fourth semiconductor chips 200, 300, 400 and 500 sequentially stacked in the third direction D3 may be disposed on the first substrate 110. However, embodiments of the present disclosure are not necessarily limited thereto.

For example, in an embodiment in which a flexible substrate is used instead of the first substrate 110, the flexible substrate may be disposed at a side, such as in the first direction D1 of the semiconductor chip structure, and each of the first to fourth semiconductor chips 200, 300, 400 and 500 included in the semiconductor chip structure may be electrically connected to circuit patterns in the flexible substrate by the conductive pad structure 240 and the conductive connection member 270.

The foregoing is illustrative of example embodiments and embodiments of the present disclosure are not necessarily limited thereto. Although a few example embodiments have been described, those skilled in the art will readily appreciate that many modifications are possible in example embodiments without materially departing from the novel teachings and advantages of the present disclosure. Accordingly, all such modifications are intended to be included within the scope of example embodiments.

What is claimed is:

1. A semiconductor package comprising:
semiconductor chips and bonding layers alternately stacked on a package substrate in a vertical direction substantially perpendicular to an upper surface of the package substrate, each of the semiconductor chips including:
a substrate; and
a conductive pad structure on the substrate;
a conductive connection member continuously extending in the vertical direction on the package substrate and directly contacting sidewalls of each of the semiconductor chips, bonding layers and the conductive pad structure; and
a molding member on the package substrate, the molding member covering sidewalls of the semiconductor chips and the conductive connection member.

2. The semiconductor package according to claim 1, wherein the conductive pad structure includes:
a sub-conductive pad on an upper surface of an edge portion of the substrate, the sub-conductive pad extending in a first direction substantially parallel to the upper surface of the package substrate; and
a conductive pad directly contacting an end portion in the first direction of the sub-conductive pad.

3. The semiconductor package according to claim 2, wherein a width of the conductive pad in a second direction substantially parallel to the upper surface of the package substrate and crossing the first direction is greater than a width of the sub-conductive pad in the second direction.

4. The semiconductor package according to claim 2, wherein a thickness of the conductive pad in the vertical direction is substantially equal to a thickness of the sub-conductive pad in the vertical direction.

5. The semiconductor package according to claim 1, wherein the conductive pad structure solely includes a conductive pad that extends in a horizontal direction substantially parallel to the upper surface of the package substrate.

6. The semiconductor package according to claim 1, further comprising:
the conductive pad structure comprises a plurality of conductive pad structures; and
the conductive connection member includes a plurality of conductive connection members,
wherein:
first ones of the plurality of conductive pad structures are disposed on each of opposite edge portions of the substrate in a first direction substantially parallel to the upper surface of the package substrate, the first ones of the plurality of conductive pad structures are spaced apart from each other in a second direction substantially parallel to the upper surface of the package substrate and crossing the first direction, and
first ones of the plurality of conductive connection members are spaced apart from each other in the second direction at each of opposite sidewalls in the first direction of each of the semiconductor chips.

7. The semiconductor package according to claim 6, wherein:
second ones of the plurality of conductive pad structures are spaced apart from each other in the first direction on each of opposite edge portions of the substrate in the second direction; and
second ones of the plurality of conductive connection members are spaced apart from each other in the first direction at each of opposite sidewalls in the second direction of each of the semiconductor chips.

8. The semiconductor package according to claim 1, wherein:
each of the semiconductor chips further includes a protective layer on the substrate, the protective layer covering a sidewall and an upper surface of the conductive pad structure; and
the bonding layers directly contact an upper surface of the protective layer.

9. The semiconductor package according to claim 8, wherein:
each of the semiconductor chips further includes a protective layer on the substrate, the protective layer covering a sidewall of the conductive pad structure and exposing an upper surface of the conductive pad structure; and
the bonding layer directly contacts an upper surface of the protective layer and an upper surface of the conductive pad structure.

10. The semiconductor package according to claim 1, wherein the conductive connection member includes gold.

11. The semiconductor package according to claim 1, wherein the conductive connection member has a shape of a semi-circle, a semi-ellipse, a polygon or a polygon with rounded corners in a plan view.

12. The semiconductor package according to claim 1, wherein sidewalls of the semiconductor chips are aligned with each other in the vertical direction.

13. A semiconductor package comprising:
semiconductor chips stacked on a package substrate in a vertical direction substantially perpendicular to an upper surface of the package substrate, each of the semiconductor chips including:
a substrate;
an insulating interlayer on the substrate, the insulating interlayer containing a wiring structure therein;
a conductive pad structure on the insulating interlayer, the conductive pad structure directly contacting the wiring structure; and
a protective layer on the insulating interlayer, the protective layer covering at least a sidewall and an upper surface of the conductive pad structure;
a bonding layer between each of the semiconductor chips in the vertical direction, the bonding layer directly contacting an upper surface of the protective layer of a first one of the semiconductor chips and a lower surface of the substrate of a second one of the semiconductor chips, the first one of the semiconductor chips is disposed under the second one of the semiconductor chips;
a conductive connection member extending in the vertical direction on the package substrate and directly contacting sidewalls of the substrate and the conductive pad structure in each of the semiconductor chips; and
a molding member on the package substrate, the molding member covering sidewalls of the semiconductor chips and the conductive connection member.

14. The semiconductor package according to claim 13, wherein the conductive pad structure solely includes a conductive pad that extends in a horizontal direction substantially parallel to the upper surface of the package substrate.

15. The semiconductor package according to claim 13, further comprising:
the conductive pad structure includes a plurality of conductive pad structures; and
the conductive connection member includes a plurality of conductive connection members,
wherein:
first ones of the plurality of conductive pad structures are disposed on each of opposite edge portions of the substrate in a first direction substantially parallel to the upper surface of the package substrate, the first ones of the plurality of conductive pad structures are spaced apart from each other in a second direction substantially parallel to the upper surface of the package substrate and crossing the first direction, and
first ones of the plurality of conductive connection members are spaced apart from each other in the second direction at each of opposite sidewalls in the first direction of each of the semiconductor chips.

16. The semiconductor package according to claim 15, wherein:
second ones of the plurality of conductive pad structures are spaced apart from each other in the first direction on each of opposite edge portions of the substrate in the second direction, and
second ones of the plurality of conductive connection members are spaced apart from each other in the first direction at each of opposite sidewalls in the second direction of each of the semiconductor chips.

17. A method of manufacturing a semiconductor package, the method comprising:
removing at least a sidewall of each semiconductor chip of a plurality of semiconductor chips to form a first opening, each of the plurality of semiconductor chips including a substrate and a conductive pad structure on the substrate, wherein the first opening exposes a sidewall of the conductive pad structure;
stacking the plurality of semiconductor chips in a vertical direction on a package substrate such that the first openings in the plurality of semiconductor chips are aligned with each other in the vertical direction, the aligned first openings forming a second opening extending in the vertical direction;
forming a conductive connection member in the second opening by a printing process or a dispensing process; and
forming a molding member on the package substrate to cover sidewalls of the plurality of semiconductor chips and the conductive connection member.

18. The method according to claim 17, wherein forming the first opening includes forming a plurality of first openings spaced apart from each other in a second direction on a sidewall in a first direction of each of the plurality of semiconductor chips, the second direction crossing the first direction.

19. The method according to claim 17, further comprising:
attaching a bonding layer on a lower surface of each of the plurality of semiconductor chips,
wherein the plurality of semiconductor chips are alternately stacked on the package substrate with the bonding layer.

20. The method according to claim 2, wherein forming the first opening includes removing a sidewall of the substrate and a sidewall of the conductive pad structure.
